(19) United States
(12) Patent Application Publication
(10) Pub. No.: US 2024/0290766 A1
(43) Pub. Date: Aug. 29, 2024

(54) INTEGRATED RADIO FREQUENCY POWERED LIGHT EMITTING DIODE CHIPS AND FABRICATION METHODS

(71) Applicant: CreeLED, Inc., Durham, NC (US)

(72) Inventors: Michael Check, Holly Springs, NC (US); Colin Blakely, Raleigh, NC (US); Jesse Reiherzer, Raleigh, NC (US)

(21) Appl. No.: 18/584,656

(22) Filed: Feb. 22, 2024

Related U.S. Application Data
(60) Provisional application No. 63/487,089, filed on Feb. 27, 2023.

(51) Int. Cl. H01L 25/16; H01L 23/00; H01L 23/29; H01L 23/31

(52) U.S. Cl. CPC H01L 25/167; H01L 23/291; H01L 23/3171; H01L 24/24; H01L 24/82; H01L 2224/24146; H01L 2924/12041; H01L 2924/1205; H01L 2924/1206; H01L 2924/1207; H01L 2924/1421

(57) ABSTRACT

A LED chip has integrated capacitor and inductor structures, wherein a capacitor structure is coupled to an active LED structure of the LED chip, the inductor structure is coupled to the capacitor structure, and the inductor structure is configured to harvest power from an externally supplied radio frequency (RF) signal. At least portions of the inductor and capacitor are arranged in or on ceramic passivation material. A LED chip may have a footprint of no greater than 2.5 mm×2.5 mm, and/or a top area of no greater than 6.25 mm². A resistor element or memristor element may be coupled between the capacitor structure and the active region. Methods of fabricating such LED chips are also provided.

### CROSS-REFERENCE TO RELATED APPLICATION(S)

This application claims priority to U.S. Provisional Patent Application No. 63/487,089 filed on Feb. 27, 2023, wherein the entire contents of the foregoing application are hereby incorporated by reference herein.

### TECHNICAL FIELD

Subject matter herein relates to solid state light-emitting diode chips incorporating inductor structures for harvesting power from radio frequency signals, devices incorporating such chips, and methods for fabricating such chips and devices.

### BACKGROUND

Solid-state lighting devices such as light-emitting diodes (LEDs) are increasingly used in both consumer and commercial applications. LEDs have been widely adopted in various illumination contexts, as well as for backlighting of liquid crystal displays and for providing sequentially illuminated LED displays. Illumination applications include automotive headlamps, roadway lamps, stadium lights, light fixtures, flashlights, and various indoor, outdoor, and specialty lighting contexts. Desirable characteristics of LED devices according to various end uses include high luminous efficacy, uniform color point over an illuminated area, long lifetime, wide color gamut, and compact size.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, indium phosphide, aluminum nitride, gallium arsenide-based materials, and/or from organic semiconductor materials. Photons generated by the active region are initiated in all directions. Lumiphoric materials, such as phosphors, may be arranged in light emission paths of LED emitters to convert portions of light to different wavelengths.

LEDs may receive electric current from grid-tied power source, or, particularly in the case of portable devices, batteries. However, batteries are subject to being depleted, and they increase the size, weight, and complexity of portable devices. There are applications in which it would be beneficial to provide small and light (e.g., portable) LED devices that dispense with the need for batteries and grid-tied power sources.

The art continues to seek improved solid-state lighting devices capable of overcoming challenges associated with conventional lighting devices, and methods for fabricating such devices.

### SUMMARY

The present disclosure relates in various aspects to solid state light emitting chips (e.g., LED chips) having integrated components that permit them to harvest power from radio frequency signals, thereby permitting such chips to be operated without need for batteries or grid-tied power sources. A LED chip has integrated capacitor and inductor structures, wherein a capacitor structure is coupled to an active LED structure of the LED chip, the inductor structure is coupled to the capacitor structure, and the inductor structure is configured to harvest power from a radio frequency (RF) signal (e.g., supplied by a RF source separated from the LED chip). At least portions of the active LED structure, the capacitor structure, and the inductor structure may be arranged in (or in contact with) a ceramic passivation material (e.g., an oxide, a nitride, or an oxynitride material) as part of an integrated LED chip structure. Integrating the capacitor and inductor structures into the LED chip permits a RF-driven LED chip to be extremely compact in size. A resistor element or memristor element may further be coupled between the capacitor structure and the active region.

In one aspect, the disclosure relates to a light-emitting diode (LED) chip that comprises: an active LED structure comprising an n-type layer, a p-type layer, and an active region arranged between the n-type layer and the p-type layer; a capacitor structure coupled to the active LED structure; a first inductor structure coupled to the capacitor structure, the first inductor structure being configured to harvest power from a radio frequency signal; and a ceramic passivation material contacting at least portions of the each of n-type layer, the p-type layer, the capacitor structure, and the first inductor structure

In another aspect, the disclosure relates to a light-emitting diode (LED) chip that comprises: an active LED structure comprising an n-type layer, a p-type layer, and an active region arranged between the n-type layer and the p-type layer; a capacitor structure coupled to the active LED structure; and a first inductor structure coupled to the capacitor structure, the first inductor structure being configured to harvest power from a radio frequency signal; wherein the LED chip has a footprint of no greater than 2.5 mm×2.5 mm (or within another threshold or range disclosed herein), or a top area when viewed from above of no more than 6.25 mm² (or within another threshold or range disclosed herein).

In certain embodiments, a LED chip further comprises a ceramic passivation material contacting at least portions of the each of n-type layer, the p-type layer, the capacitor structure, and the first inductor structure.

In certain embodiments, the ceramic passivation material comprises an oxide, a nitride, or oxynitride material.

In certain embodiments, wherein at least a portion of each of the capacitor structure and the first inductor structure is arranged within 500 microns of the active region.

In certain embodiments, the capacitor structure comprises a first proximal electrode coupled to the n-type layer, and comprises a first distal electrode that is separated from the first proximal electrode; and a portion of the ceramic passivation material is arranged between the first proximal electrode and the first distal electrode.

In certain embodiments, the LED chip further comprises a resistor element arranged in contact with the ceramic passivation material, and coupled between the capacitor structure and the active LED structure.

In certain embodiments, the LED chip further comprises a memristor structure arranged in contact with the ceramic passivation material, and coupled between the capacitor structure and the active LED structure.

In certain embodiments, the LED chip further comprises a substrate that comprises a light-transmissive material and that is configured to permit transmission of at least a portion of light emissions of the active LED structure.

In certain embodiments, the substrate comprises a patterned surface including at least one of (a) a plurality of recessed features and (b) a plurality of raised features, wherein the active LED structure is adjacent to the patterned surface of the substrate

In certain embodiments, the LED chip further comprises at least one reflector layer configured to reflect emissions of active region toward the substrate, wherein the active LED structure is arranged between the substrate and the at least one reflector layer.

In certain embodiments, the LED chip further comprises at least one barrier layer contacting the at least one reflector layer and configured to inhibit migration of metal atoms of the at least one reflector layer.

In certain embodiments, a central area of the LED chip is laterally surrounded by a peripheral area, wherein the active region is arranged in the central area, and the first inductor structure is arranged in the peripheral area.

In certain embodiments, the LED chip further comprises a first electrical contact coupled to the n-type layer; and a second electrical contact coupled to the p-type layer.

In certain embodiments, each of the first electrical contact and the second electrical contact is exposed along an exterior of the LED chip.

In certain embodiments, the capacitor structure and the first inductor structure are encapsulated within the ceramic passivation material and not exposed along an exterior surface of the LED chip.

In certain embodiments, the LED chip further comprises a second inductor structure.

In another aspect, the disclosure relates to a method for fabricating a LED chip, the method comprising: growing an active LED structure on a substrate, the active LED structure comprising an n-type layer, a p-type layer, and an active region arranged between the n-type layer and the p-type layer; forming a mesa including mesa sidewalls that bound the active region; depositing a first metal-containing layer, wherein a central portion of the first metal-containing layer is deposited over the mesa to form a mirror structure, and a peripheral portion of the first metal-containing layer is arranged to form a proximal capacitor electrode; depositing a ceramic passivation material over the first metal-containing layer; etching portions of the ceramic passivation material; and depositing a second metal-containing layer to form a first inductor structure and a distal capacitor electrode.

In certain embodiments, the ceramic passivation material comprises an oxide, a nitride, or oxynitride material.

In certain embodiments, at least a portion of each of the capacitor structure and the first inductor structure is arranged within 500 microns of the active region.

In certain embodiments, the method further comprises forming a resistor element coupled between the capacitor structure and the active LED structure.

In certain embodiments, the method further comprises forming a memristor structure coupled between the capacitor structure and the active LED structure,

In certain embodiments, the substrate comprises a patterned surface including at least one of (a) a plurality of recessed features and (b) a plurality of raised features, wherein the active LED structure is adjacent to the patterned surface of the substrate.

In certain embodiments, the method further comprises forming a first electrical contact coupled to the n-type layer, and forming a second electrical contact coupled to the p-type layer.

In certain embodiments, each of the first electrical contact and the second electrical contact is exposed along an exterior of the LED chip.

In another aspect, any of the foregoing aspects, and/or various separate aspects and features as described herein, may be combined for additional advantage. Any of the various features and elements as disclosed herein may be combined with one or more other disclosed features and elements unless indicated to the contrary herein.

Other aspects, features and embodiments of the present disclosure will be more fully apparent from the ensuing disclosure and appended claims.

### BRIEF DESCRIPTION OF THE DRAWINGS

FIG. 1 is a simplified circuit diagram showing a solid state light emitting chip according to one embodiment of the present disclosure, the solid state chip incorporating a light emitting diode, a capacitor, a resistor element, and an inductor arranged to harvest power from a radio frequency signal.

FIG. 2 is a cross-sectional view of a solid state light emitting chip including the elements of FIG. 1 according to one embodiment, the chip incorporating a light emitting diode in a flip-chip configuration, together with a capacitor, a resistor element, an inductor, and exposed electrical contacts.

FIG. 3 is a cross-sectional view of another solid state light emitting chip including the elements of FIG. 1 according to one embodiment, the chip incorporating a light emitting diode in a flip-chip configuration, together with a capacitor, a resistor element, and an inductor, but with non-exposed electrical contacts encapsulated in passivation material.

FIG. 4 is a top plan view of a solid state light emitting chip including the elements of FIG. 1 according to one embodiment.

FIGS. 5A-5F are top views of horizontal sections of a solid state light emitting chip including the elements of FIG. 1 according to one embodiment.

FIG. 6 is a simplified circuit diagram showing a solid state light emitting chip according to one embodiment of the present disclosure, the solid state chip incorporating a light emitting diode, a capacitor, a resistor element, and first and second inductors arranged to harvest power from radio frequency signals.

FIG. 7 is a cross-sectional view of a solid state light emitting chip including the elements of FIG. 6 according to one embodiment, the chip incorporating a light emitting diode in a flip-chip configuration, together with a capacitor, a resistor element, two inductors, and exposed electrical contacts.

FIG. 8 is a simplified circuit diagram showing a solid state light emitting chip according to one embodiment of the present disclosure, the solid state chip incorporating a light emitting diode, a capacitor, a memristor structure, and an inductor arranged to harvest power from a radio frequency signal.

FIG. 9 is a cross-sectional view of a solid state light emitting chip including the elements of FIG. 8 according to one embodiment, the chip incorporating a light emitting diode in a flip-chip configuration, together with a capacitor, a memristor structure, and an inductor arranged to harvest power from a radio frequency signal.

FIG. 10 is a solid state light emitting chip according to one embodiment, the chip incorporating a light emitting diode in a flip-chip configuration, together with a capacitor, a memristor structure, and first and second inductors arranged to harvest power from radio frequency signals.

FIG. 11 schematically illustrates a system configured to permit wireless communication between one or more RF transmitters and devices incorporating one or more LED chips having integrated inductor structures suitable for harvesting power from signals generated by the RF transmitters.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Before delving into specific details of various aspects of the present disclosure, an overview of various elements that may be included in exemplary LEDs of the present disclosure is provided for context. A LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (AI), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), indium phosphide (InP), and related compounds.

The active LED structure may be grown on a growth substrate that can include many materials, such as sapphire, SiC, aluminum nitride (AlN), GaN, GaAs, glass, or silicon. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light-transmissive optical properties.

Different embodiments of the active LED structure can emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. In certain embodiments, the active LED structure may be configured to emit light that is outside the visible spectrum, including one or more portions of the ultraviolet (UV) spectrum.

A LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. A LED source and one or more lumiphoric materials may be selected such that their combined output results in light with one or more desired characteristics such as color, color point, intensity, spectral density, etc. In certain embodiments, aggregate emissions of LED chips, optionally in combination with one or more lumiphoric materials, may be arranged to provide cool white, neutral white, or warm white light, such as within a color temperature range of 2500 Kelvin (K) to 10,000 K. In certain embodiments, lumiphoric materials having cyan, green, amber, yellow, orange, and/or red peak wavelengths may be used. In certain embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. In other embodiments, the LED chip and corresponding lumiphoric material may be configured to primarily emit converted light from the lumiphoric material so that aggregate emissions include little to no perceivable emissions that correspond to the LED chip itself.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described may also be applicable to flip-chip structures where anode and cathode connections are made from a same side of the LED chip for flip-chip mounting to another surface.

Solid state light emitting chips (e.g., LED chips) according to embodiments disclosed herein include integrated components that permit them to harvest power from radio frequency signals, thereby permitting such chips to be operated without need for batteries or grid-tied power sources. In certain embodiments, a LED chip has integrated capacitor and inductor structures, wherein a capacitor structure is coupled to an active LED structure of the LED chip, the inductor structure is coupled to the capacitor structure, and the inductor structure is configured to harvest power from a radio frequency (RF) signal (e.g., supplied by a RF source separated from the LED chip). At least portions of the active LED structure, the capacitor structure, and the inductor structure may be arranged in (or in contact with) a ceramic passivation material (e.g., an oxide, a nitride, or an oxynitride material) as part of an integrated LED chip structure. Integrating the capacitor and inductor structures into the LED chip permits a RF-driven LED chip to be extremely compact in size, wherein in certain embodiments the entire LED chip may have a footprint of no greater than 2.5×2.5 mm, or a footprint no greater than 2.0 mm×2.0 mm, or a footprint no greater than 1.5 mm×1.5 mm, or a footprint no greater than 1.0 mm×1.0 mm, or a footprint no greater than 0.5 mm×0.5 mm, or a footprint in a range between any two or more of the foregoing values. In certain embodiments, the entire LED chip may have a top area (i.e., two dimensional area when viewed from above) of no more than 6.25 mm², of no more than 4 mm², of no more than 2.25 mm², of no more than 1 mm², or of no more than 0.25 mm², or a top area within a range between any two or more of the foregoing values. A LED chip may have a shape when viewed from above that is rectangular, polygonal, round, or any other suitable shape. In certain embodiments, at least a portion of each of a capacitor structure and an inductor structure may be arranged within 500 microns of an active region of a LED chip. Various additional features and structures (e.g., resistors, memristors, etc.) may be provided in a RF-driven LED chip according to embodiments herein. Integration of power harvesting structures in a LED chip permits functional elements to be placed in close proximity and permits reduced chip sizes that would not be achievable in a non-integrated format (e.g., with separately fabricated elements such as LED, inductor, capacitor, resistor/memristor being mounted to a circuit board and connected by traces thereon).

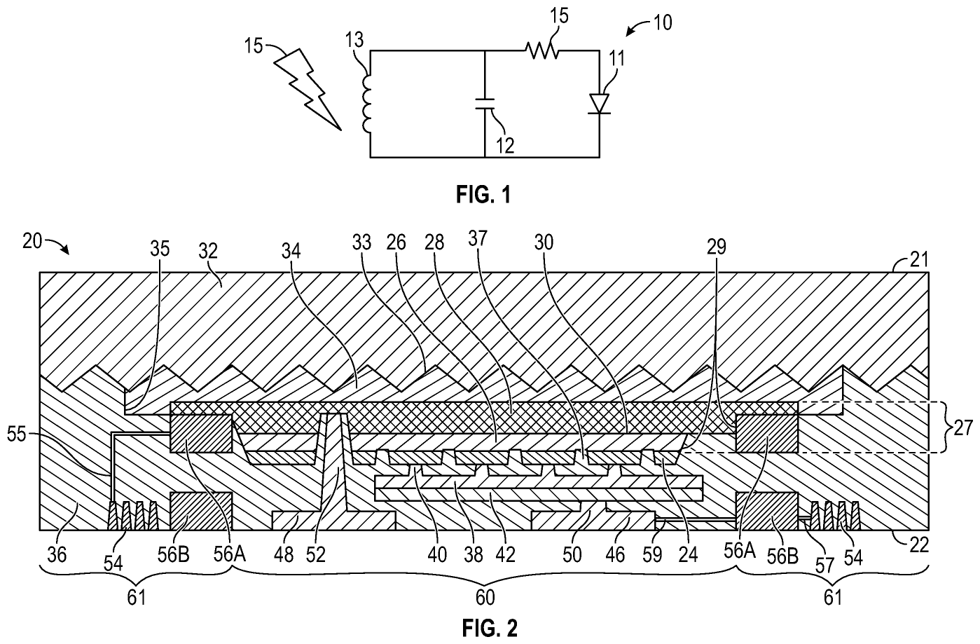

FIG. 1 is a simplified circuit diagram showing a solid state light emitting (e.g., LED) chip 10 according to one embodiment of the present disclosure, the chip 10 incorporating a light emitting diode (LED) 11, a capacitor structure 12, a resistor element 15, and an inductor structure 13 arranged to harvest power from a radio frequency (RF) signal provided by a RF source 16 that is separate from the LED chip 10. The inductor structure 13 is configured to receive a RF signal from the RF source 16 and produce current that is stored in the capacitor structure 12. The resistor element 15 may be used to limit current flow through the LED 11, thereby protecting the LED 11. When sufficient charge is accumulated in the capacitor structure 12, current will flow through the resistor element 15 to the light emitting diode 11 and produce light emissions. The various elements of FIG. 1 are supported by a single substrate (not shown) as part of the LED chip 10.

FIG. 2 is a cross-sectional view of a portion of a LED chip 20 arranged in a flip-chip configuration, with the LED chip 20 including an integrated inductor structure 54, capacitor electrodes 56A-56B (which may also be termed “capacitor plates” herein), and a resistor element 58 all arranged in passivation material 36 and configured to permit the LED chip 20 to be powered by radio frequency energy harvested from a source (not shown) separate from the LED chip 20. The LED chip includes an active LED structure 27 comprising a p-type semiconductor layer 26, an n-type semiconductor layer 28, and an active layer region 30 (at an interface between the p-type layer 26 and the n-type layer 28, arranged in a central region 60 of the LED chip 20) formed on a substrate 32 having a light extraction surface 21. In certain embodiments, one or more buffer layers and/or undoped layers 34 may be provided between the substrate 32 and the active LED structure 27. The substrate 32 may embody a patterned substrate such that a surface 33 of the substrate 32 proximate to the buffer and/or undoped layers 34, or otherwise closest to the active LED structure 27, is patterned. In certain embodiments, the n-type layer 28 is between the active layer region 30 and the substrate 32. In other embodiments, the doping order may be reversed. The substrate 32 can comprise many different materials such as SiC or sapphire, and can have one or more surfaces that are shaped, textured, or patterned to enhance light extraction. In certain embodiments, the substrate 32 is light transmissive (preferably transparent) and may include a patterned surface 33 that is proximate to the active LED structure 27 and includes multiple recessed and/or raised features.

A current spreading layer 24 (which may be formed of a transparent conductive oxide such as indium tin oxide (ITO), a metal such as platinum (Pt), or another suitable material) is arranged against portions of the p-type layer 26 and serves to laterally spread current before such current is injected into the p-type semiconductor layer 26, thereby providing increased current injection area. While providing such benefits, the current spreading layer 24 may negatively impact luminous efficacy by absorbing some percentage of light generated by the active LED structure 27. To partially mitigate this issue, the current spreading layer 24 may be formed in segments across the p-type semiconductor layer 26 so that portions of the passivation material 36 may form an index of refraction step with the p-type semiconductor layer 26 so that at least some light reaching this interface may be redirected or reflected, wherein passivation material segments 37 are arranged between different segments of the current spreading layer 24. Additionally, separating the current spreading layer 24 into segments allows fine tuning of current injection across the p-type semiconductor layer 26. The passivation material 36 protects and provides electrical insulation for the LED chip 20 and can comprise many different materials, such as a dielectric material. In certain embodiments, the passivation material 36 is deposited in multiple layers of one or more passivation materials. Examples of suitable materials for the passivation material 36 include but are not limited to SiO₂, SiN, SiNx, and/or Si₃N₄.

With continued reference to FIG. 2, at least one reflective layer 38 (which may embody a single layer or multiple layers) is arranged proximate to the current spreading layer 24. In certain embodiments, the at least one reflective layer may include a metal layer (e.g., Ag, Au, Al, or combinations thereof) that is configured to reflect light emanating from the active LED structure 27. As illustrated, the at least one reflective layer includes multiple interconnects 40 extending through the passivation material 36 to contact the current spreading layer 24. In certain embodiments, the reflective layer interconnects 40 comprise reflective layer vias. Accordingly, the at least one reflective layer 38 and the reflective layer interconnects 40 form a reflective structure of the LED chip 20. In some embodiments, the reflective layer interconnects 40 comprise the same material as the at least one reflective layer 38 and are formed concurrently with the at least one reflective layer 38. In other embodiments, the reflective layer interconnects 40 may comprise a different material than the at least one reflective layer 38. The LED chip 20 may further include a barrier layer 42 adjacent to the at least one reflective layer 38 to prevent migration of reflective layer material(s), such as Ag, to other layers. Preventing this migration helps the LED chip 20 maintain efficient operation through its lifetime. The barrier layer 42 may comprise an electrically conductive material, with suitable materials including but not limited to sputtered Ti/Pt followed by evaporated Au bulk material or sputtered Ti/Ni followed by an evaporated Ti/Au bulk material.

The LED chip 20 includes a p-contact 46 and an n-contact 48 that are partially embedded in the passivation material 36 and accessible along a rear surface 22 of the chip 20, with the p-contact 46 and an n-contact 48 being configured to permit electrical connections to be made with the active LED structure 27. The p-contact 46, which may also be referred to as an anode contact, may comprise one or more p-contact interconnects 50 that extend through the passivation material 36 to the barrier layer 42 or the at least one reflective layer 38 to provide an electrical path to the p-type layer 26. In certain embodiments, the one or more p-contact interconnects 50 comprise one or more p-contact vias. The n-contact 48, which may also be referred to as a cathode contact, may comprise one or more n-contact interconnects 52 that extend through the passivation material 36, the current spreading layer 24, the p-type layer 26, and the active layer 30 to provide an electrical path to the n-type layer 28. In certain embodiments, the one or more n-contact interconnects 52 comprise one or more n-contact vias.

The p-contact 46 and the n-contact 48 can comprise many different materials such as Au, copper (Cu), nickel (Ni), In, Al, Ag, tin (Sn), Pt, or combinations thereof. In still other embodiments, the p-contact 46 and the n-contact 48 can comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used can depend on the location of the contacts and on the desired electrical characteristics, such as transparency, junction resistivity, and sheet resistance. As described above, the LED chip 20 is arranged for flip-chip mounting and the p-contact 46 and n-contact 48 enable the chip 20 to be mounted or bonded to a surface, such as a printed circuit board. While FIG. 2 is described in the context of a flip-chip structure, the principles disclosed for the chip (including presence of inductor, capacitor, and resistor structures) are readily applicable to other chip structures.

The LED chip 20 additionally includes an inductor structure 54 arranged proximate to a rear surface 22 of the LED chip 20. Although FIG. 2 shows the inductor structure in two locations, it is to be appreciated that the inductor structure 54 comprises continuous traces of conductive material (e.g., metal) at least partially embedded in the passivation material 36 to form a single coil that extends around a peripheral region 61 of the LED chip 20. A capacitor structure is further provided, including proximal and distal capacitor electrodes or plates 56A, 56B that are spaced apart by a thickness of passivation material 36, wherein the proximal capacitor electrode or plate 56A is fully embedded in the passivation material 36, and the distal capacitor electrode or plate 56B is partially embedded in the passivation material 36 with a portion thereof being exposed along the rear surface 22 of the chip 20. The dimensions, spacing, and materials of the proximal and distal capacitor plates 56A, 56B, which are also arranged in a peripheral region 61 of the LED chip, may be adjusted to provide a desired capacitance value. The proximal capacitor plate 56A is arranged in contact with the n-type layer 28, and is coupled to the inductor structure 54 via conductive trace 55, which may include a vertically-extending via portion as well as a horizontal portion in combination serving as an interconnect extending through the passivation material 36. The distal capacitor plate 56B is at least partially embedded in the passivation material 36 and exposed along the rear surface 22, is coupled to the inductor structure 54 using conductive trace 57, and is coupled to the p-contact 46 using a resistor element 59, wherein the conductive trace 57 and the resistor element 59 both extend horizontally through the passivation material 36.

During fabrication of the LED chip 20, the substrate 32 may be patterned along surface 33, with the buffer and/or undoped layers 34 grown thereon. The n-type layer 28 and p-type layer 26 are grown on the buffer and/or undoped layers 34. Thereafter, peripheral portions of the n-type layer 28, p-type layer 26, and buffer and/or undoped layers 34 may be subjected to etching or another suitable material removal technique to form a mesa structure that protrudes relative to the substrate 32, with the mesa structure being laterally bounded by buffer or undoped layer sidewalls 35 as well as semiconductor layer sidewalls 29, which bound the active region 30. The current spreading layer 24 is formed over the p-type layer, and a portion of the passivation material 36 may be provided over the current spreading layer 24. Thereafter, at least one metal-containing layer may be deposited over the current spreading layer 24 and a central portion of passivation material 36 to form the reflector layer 38 in a central region 60 of the chip 20, wherein the at least one metal-containing layer may also be deposited over peripheral portions of the n-type layer 28 to form proximal plates 56A of the capacitor structure in the peripheral region 61 of the chip 20. The barrier layer 42 may be formed over the reflector layer 38. After deposition of additional passivation material 36, portions of the passivation material 36 may be etched to form recesses, and at least one metal-containing layer may be deposited to form the inductive structure 54, the distal capacitor plate 56B, the resistor element 59, and interconnects 55, 57. At the same time, or in a different step, the n-contact 48, p-contact 46, and related interconnects 52, 50 may be formed by metal deposition (e.g., following etching to form recesses into which metal is deposited).

In wireless operation of the LED chip 20, a RF signal generated by an external source (not shown) is received by the inductor structure 54, causing current to be conducted through conductive trace 55 to the proximal capacitor plate 56A, causing charge to accumulate between the capacitor plates 56A, 56B. When sufficient charge has accumulated between the capacitor plates 56A, 56B, current will flow from the proximal capacitor plates 56A through the n-type layer 28, the active layer 30, the p-type layer 26, the current spreading layer 24, the reflector layer 38, the barrier layer 42, the p-contact 46, and the resistor element 56 to the distal capacitor plate 56B, causing photons (light) to be emitted by the active layer 30. Such light is reflected by the reflector layer 30 toward the substrate 32 to exit through the light extraction surface 21.

Because the p-contact 46 and the n-contact 48 are exposed along the rear surface 22 of the LED chip 20, the LED chip 20 may also be illuminated by a battery or grid-tied power source coupled thereto. In such operation, a signal applied across the p-contact 46 and the n-contact 48 is conducted to the p-type layer 26 and the n-type layer 28, causing the LED chip 20 to emit light from the active layer 30. Thus, the LED chip 20 may be illuminated by conduction of a wired signal, or by receipt of a wireless RF signal.

Although the LED chip 20 shown in FIG. 2 includes a p-contact 46 and an n-contact 48 that are exposed along the rear surface 22 of the LED chip 20 and that permit the LED chip 20 to be conductively coupled to an external current source, such contacts 46, 48 (as well as the inductor structure 54 and distal capacitor plates 56B) need not be exposed in certain embodiments, since presence of the inductor structure 54 permits current to be harvested wirelessly from a RF source 16 that is separate from the LED chip 10.

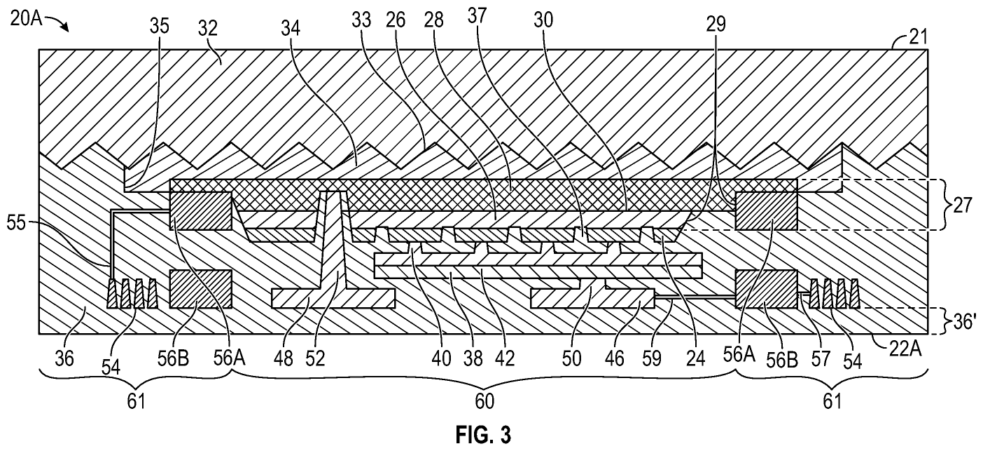

FIG. 3 is a cross-sectional view of a solid state LED chip 20A including all of the items described in connection with FIG. 2, but in an embodiment having non-exposed electrical contacts (i.e., p-contact 46 and n-contact 48) that are encapsulated in passivation material 36. The LED chip 20A includes a rear portion 36′ of passivation material 36 that extends to the rear surface 22A of the LED chip 20A, thereby causing the inductor structure 54, distal capacitor plate 56B, p-contact 46, and n-contact 48 to be fully encapsulated in passivation material 36 and therefore not exposed along the rear surface 22A. All remaining elements of FIG. 3 are identical to those described in connection with FIG. 2, such that the description of FIG. 2 is hereby incorporated by reference with respect to FIG. 3. In operation of the LED chip 20A, a RF signal generated by an external source (not shown) is received by the inductor structure 54, causing current to be conducted through conductive trace 55 to the proximal capacitor plate 56A, causing charge to accumulate between the capacitor plates 56A, 56B. When sufficient charge has accumulated between the capacitor plates 56A, 56B, current will flow from the proximal capacitor plates 56A through the n-type layer 28, the active layer 30, the p-type layer 26, the current spreading layer 24, the reflector layer 38, the barrier layer 42, the p-contact 46, and the resistor element 56 to the distal capacitor plate 56B, causing photons (light) to be emitted by the active layer 30. Such light is reflected by the reflector layer 30 toward the substrate 32 to exit through the light extraction surface 21.

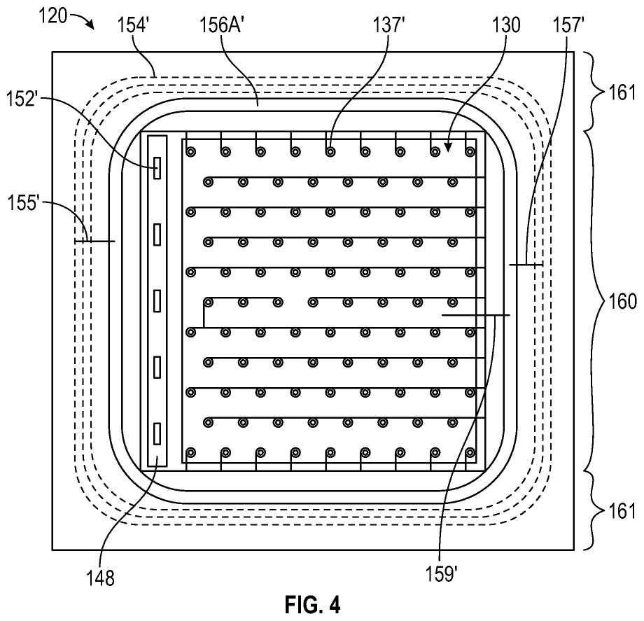

FIG. 4 is a top plan view of a solid state LED chip 120 including elements consistent with those shown in FIGS. 2-3, with such view being provided to show placement of the inductor structure 154′ and proximal capacitor plate 156A′ in the peripheral region 161 of the LED chip 120 to laterally surround the active layer region 130 being located in the central portion 160 thereof. Passivation material segments 130 are dispersed under the active layer region 130 in the central region 160. The proximal capacitor plate 156A is coupled to the inductor structure 154 via conductive trace 155′. The distal capacitor plate (arranged below the proximal capacitor plate 156A and separated by passivation material) is coupled to the inductor structure 154′ by another conductive trace 157′, and is further coupled to a p-contact (not shown, below the active layer region 130) by resistor 159′.

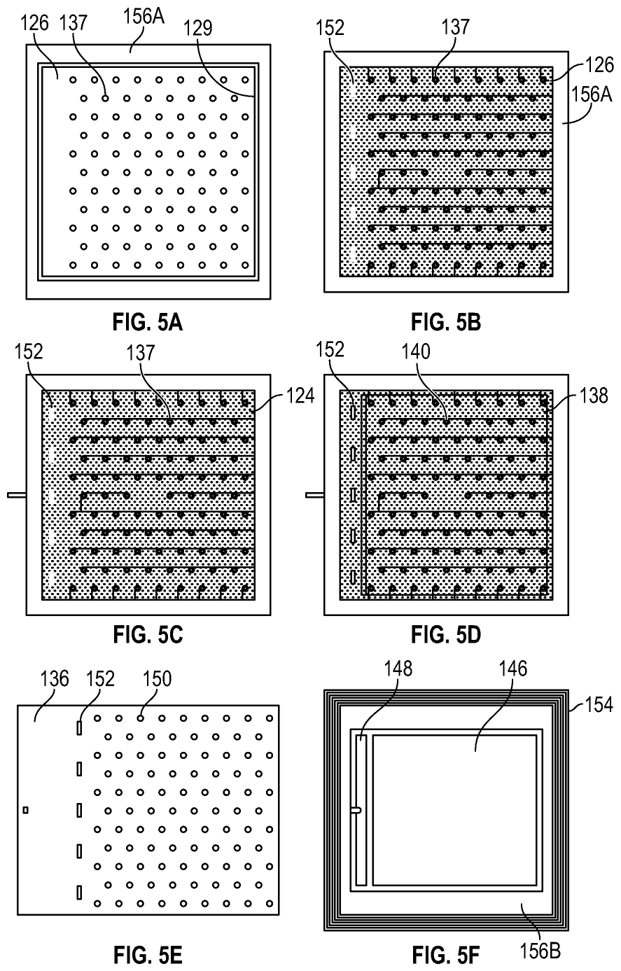

FIGS. 5A-5F are top views of horizontal sections of a solid state LED chip according to one embodiment that includes the elements of FIG. 1, in a layout substantially similar to the embodiment of FIG. 4. FIG. 5A illustrates a mesa structure including a n-type semiconductor layer 128 having peripheral semiconductor sidewalls 129, with a proximal capacitor plate 156A arranged around a perimeter of the mesa. Although passivation material segments 137 are shown through the n-type semiconductor layer 128, they are not arranged in contact with a bottom surface thereof. FIG. 5B illustrates a p-type semiconductor layer 126, with the proximal capacitor plate 156A arranged around a perimeter thereof. Passivation material segments 137 are in contact with the p-type semiconductor layer 126, with n-contact interconnect vias 152 extending through the p-type semiconductor layer 126. FIG. 5C shows a current spreading layer 127 with passivation material segments 137 and n-contact interconnect vias 152 extending therethrough. FIG. 5D shows a mirror layer 138 with associated interconnects 140 to be arranged below the current spreading layer 127, with n-contact interconnect vias 152 extending through the mirror layer 138. FIG. 5E shows an interlayer of passivation material 136 with p-contact interconnects 150 and n-contact interconnect vias 152 extending therethrough. FIG. 5F shows a die attach layer including the inductive structure 154 surrounding a distal capacitor plate 156 and both arranged in a peripheral region that surrounds a n-contact 148 and a p-contact 146 both arranged in a central region. The various structures shown in FIG. 5A-5F are analogous to structures shown in cross-sectional view in FIG. 2.

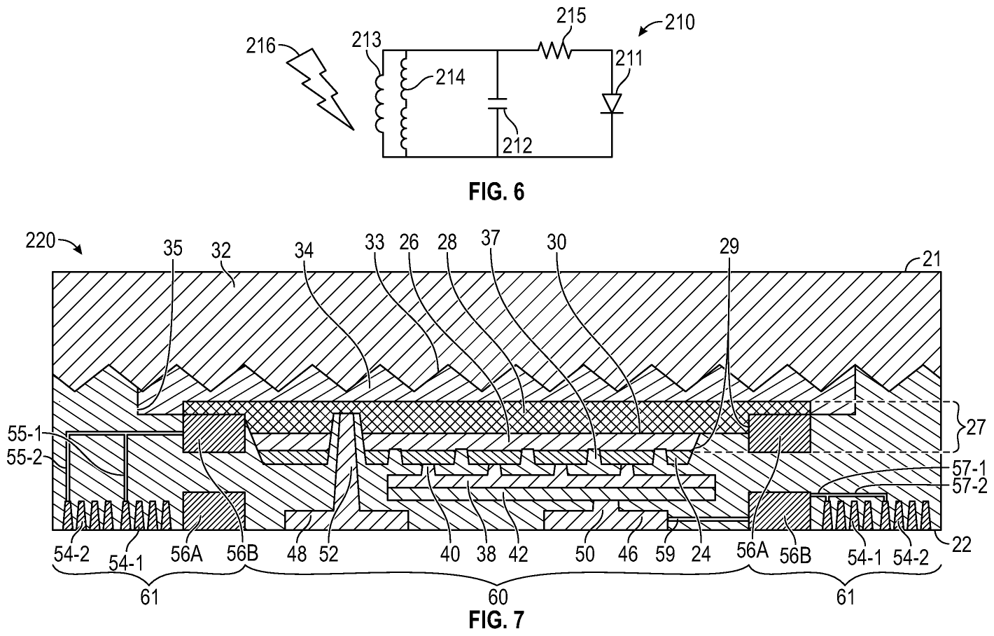

In certain embodiments, a solid state light emitting chip configured for harvesting power from a RF signal may incorporate multiple inductor structures, which may be configured for receiving RF signals of different frequencies. One example of such an arrangement is schematically illustrated in FIG. 6.

FIG. 6 is a simplified circuit diagram showing a solid state light emitting (e.g., LED) chip 210 according to one embodiment of the present disclosure, the chip 210 incorporating a light emitting diode (LED) 211, a capacitor structure 212, a resistor element 215, and first and second inductor structures 213, 214 arranged to harvest power from radio frequency (RF) signals provided by one or more RF sources 216 that are separate from the LED chip 210. The first inductor structure 213 is configured to receive a RF signal at a first frequency from the at least one RF source 216 and produce current that is stored as electrical charge in the capacitor structure 212. Similarly, the second inductor structure 214 is configured to receive a RF signal at a second frequency from the at least one RF source 216 and produce current that is stored as electrical charge in the capacitor structure 212. In certain embodiments, multiple RF sources 216 configured to produce RF signals at differing frequencies may be provided. The resistor element 215 may be used to limit current flow through the LED 211, thereby protecting the LED 211. When sufficient charge is accumulated in the capacitor structure 212, current will flow through the resistor element 215 to the light emitting diode 211 and produce light emissions. The various elements of FIG. 6 are supported by a single substrate (not shown) as part of the LED chip 210.

FIG. 7 is a cross-sectional view of a solid state LED chip 220 including all of the items previously described in connection with FIG. 2, but in an embodiment having multiple inductor structures 54-1, 54-2 instead of just one inductor structure (i.e., inductor 54 as shown in FIG. 2). Although FIG. 7 shows the inductor structures 54-1, 54-2 in two locations, it is to be appreciated that each inductor structure 54-1, 54-2 comprises a continuous traces of conductive material (e.g., metal) at least partially embedded in the passivation material 36 to form a single coil that extends around a peripheral region 61 of the LED chip 220. A capacitor structure is further provided, including proximal and distal capacitor plates 56A, 56B that are spaced apart by a thickness of passivation material 36, wherein the proximal capacitor plate 56A is fully embedded in the passivation material 36, and the distal capacitor plate 56B is partially embedded in the passivation material 36. The inductor structures 54-1, 54-2 and the distal capacitor plate 56B are arranged proximate a rear surface 22 of the LED chip 220. A first conductive trace 55-1, which may include a vertically-extending via portion as well as a horizontal portion in combination serving as an interconnect, extend through the passivation material 36 to couple the first inductor structure 54-1 to the proximal capacitor plate 56B. Similarly, a second conductive trace 55-2, which may include a vertically-extending via portion as well as a horizontal portion in combination serving as an interconnect, extend through the passivation material 36 to couple the second inductor structure 54-2 to the proximal capacitor plate 56B. The proximal capacitor plate 56A is arranged in contact with the n-type layer 28. The distal capacitor plate 56B is at least partially embedded in the passivation material 36 and exposed along the rear surface 22, is coupled to the inductor structures 54-1, 54-2 using conductive traces 57-1, 57-2, and is coupled to the p-contact 46 using a resistor element 59, wherein the conductive trace 57 and the resistor element 59 both extend horizontally through the passivation material 36. Although FIG. 7 shows the LED chip 220 as having exposed electrical contacts (i.e., n-contact 48 and p-contact 46) and having inductor elements 54-1, 54-2 and distal capacitor plate 56B arranged proximate to the rear surface 22 of the LED chip 220, it is to be appreciated that these elements may be encased in passivation material in certain embodiments (e.g., including a rear portion 36′ of passivation material 36 as shown in FIG. 3) and therefore spaced apart from the rear surface 22 of the LED chip 220. All remaining elements of FIG. 7 are identical to those described in connection with FIG. 2, such that the description of FIG. 2 is hereby incorporated by reference with respect to FIG. 7.

In operation of the LED chip 220, a first RF signal generated by an external source (not shown) is received by the first inductor structure 54-1, causing current to be conducted through conductive trace 55-1 to the proximal capacitor plate 56A, thereby causing charge to accumulate between the capacitor plates 56A, 56B. Separately, or additionally, a second RF signal generated by an external source (not shown) is received by the second inductor structure 54-2, causing current to be conducted through conductive trace 55-2 to the proximal capacitor plate 56A, thereby causing charge to accumulate between the capacitor plates 56A, 56B. When sufficient charge has accumulated between the capacitor plates 56A, 56B, current will flow from the proximal capacitor plates 56A through the n-type layer 28, the active layer 30, the p-type layer 26, the current spreading layer 24, the reflector layer 38, the barrier layer 42, the p-contact 46, and the resistor element 56 to the distal capacitor plate 56B, causing photons (light) to be emitted by the active layer 30. Such light is reflected by the reflector layer 30 toward the substrate 32 to exit through the light extraction surface 21.

In certain embodiments, a solid state LED chip configured for harvesting power from a RF signal may incorporate a memristor structure in lieu of a resistor. A memristor is a non-linear two-terminal electrical component relating electric charge and magnetic flux linkage. A memristor shows the behavior of a non-linear resistor and shows non-volatile or volatile memory properties, by remembering or recollecting the amount of charge that has previously flowed through it, even when power is no longer present. Restated, in a memristor, the resistance is not constant and depends on the history of current passed through the memristor. A memristor may include metal that is permitted to diffuse in a lattice when exposed to sufficiently high charge, thereby altering resistance properties. This diffusion may be partially or fully reversed in at least some cases by heating the memristor, thereby resetting the element to a normal resistance state. Examples of known memristors include, but are not limited to, structures based on titanium oxide (TiO₂) metal-insulator-metal (MIM) designs, layered MoS₂ devices with grain boundary regions, and devices containing MoOₓ/MoS₂.

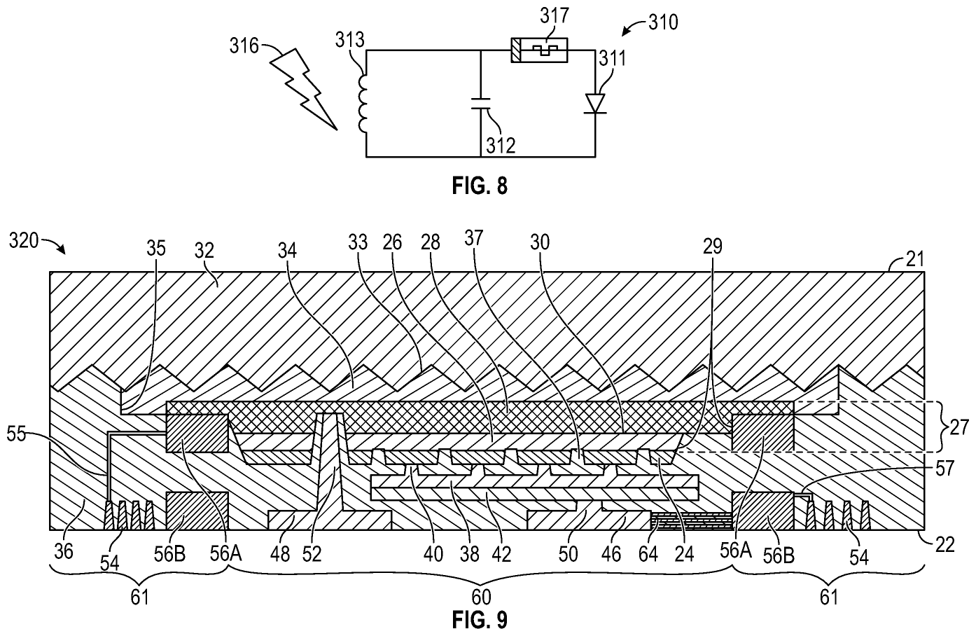

FIG. 8 is a simplified circuit diagram showing a solid state light emitting (e.g., LED) chip 310 according to one embodiment of the present disclosure, the chip 310 incorporating a light emitting diode (LED) 311, a capacitor structure 312, a memristor element 317, and an inductor structures 313 configured to harvest power from radio frequency (RF) signals provided by one or more RF sources 316 that are separate from the LED chip 310. The inductor structure 313 is configured to receive a RF signal from the at least one RF source 316 and produce current that is stored as electrical charge in the capacitor structure 313. The memristor element 317 may be used to limit current flow through the LED 311. When sufficient charge is accumulated in the capacitor structure 312, current will flow through the resistor element 315 to the light emitting diode 311 and produce light emissions. If a high level of charge is supplied to the memristor element 317, then a resistance value thereof may change, thereby altering the current that may be supplied to the LED 311 and affecting brightness of its output emissions. In this regard, the memristor element 317 in series with the LED 311 enables the LED 311 to provide visual indication of an altered state of the memristor element 317, which may be useful in security and other applications. The various elements of FIG. 6 are supported by a single substrate (not shown) as part of the LED chip 310.

FIG. 9 is a cross-sectional view of a solid state LED chip 320 including all of the elements described in connection with FIG. 2, but in an embodiment in which the resistor element 59 of FIG. 2 is replaced with a memristor 64, which is arranged between the distal capacitor plate 56B and the p-contact 46. Although FIG. 9 shows the LED chip 320 as having exposed electrical contacts (i.e., n-contact 48 and p-contact 46) and having an inductor element 54 and distal capacitor plate 56B arranged proximate to the rear surface 22 of the LED chip 320, it is to be appreciated that these elements may be encased in passivation material in certain embodiments (e.g., including a rear portion 36′ of passivation material 36 as shown in FIG. 3) and therefore spaced apart from the rear surface 22 of the LED chip 320. Other than inclusion of a memristor 64, all remaining elements of FIG. 9 are identical to those described in connection with FIG. 2, such that the description of FIG. 2 is hereby incorporated by reference with respect to FIG. 9. In operation of the LED chip 320, a RF signal generated by an external source (not shown) is received by the inductor structure 54, causing current to be conducted through conductive trace 55 to the proximal capacitor plate 56A, and causing charge to accumulate between the capacitor plates 56A, 56B. When sufficient charge has accumulated between the capacitor plates 56A, 56B, current will flow from the proximal capacitor plates 56A through the n-type layer 28, the active layer 30, the p-type layer 26, the current spreading layer 24, the reflector layer 38, the barrier layer 42, the p-contact 46, and the memristor element 64 to the distal capacitor plate 56B, causing photons (light) to be emitted by the active layer 30. Such light is reflected by the reflector layer 30 toward the substrate 32 to exit through the light extraction surface 21. If a sufficiently high level of charge is supplied to the memristor element 64, then a resistance value thereof may be altered and maintained in an altered state, thereby altering amount of current that may be supplied to the active layer 30 and altering emissions of the LED chip 320. If desired, the altered resistance value of the memristor element 64 may be returned to an original state by heating the LED chip 320. Since the LED chip 320 in the illustrated embodiment includes exposed electrical contacts (i.e., n-contact 48 and p-contact 46), the LED chip 320 may also be operated by supplying electrical potential across the electrical contacts 46, 48.

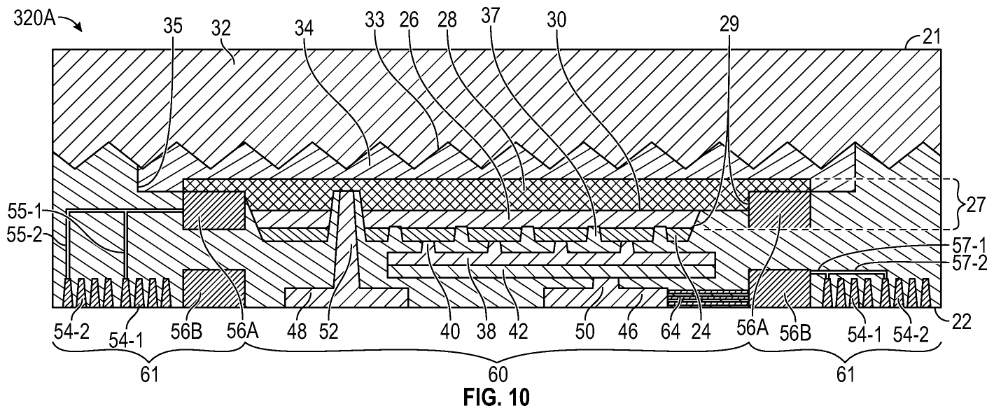

In certain embodiments, a solid state light emitting chip configured for harvesting power from a RF signal may incorporate multiple inductor structures (which may be configured for receiving RF signals of different frequencies) in combination with a memristor structure. One example of such a structure is illustrated in FIG. 10. FIG. 10 is a cross-sectional view of a solid state LED chip 320A including all of the elements described in connection with FIG. 7 (including multiple inductor structures 54-1, 54-2), but in an embodiment in which the resistor element 59 of FIG. 7 is replaced with a memristor 64, which is arranged between the distal capacitor plate 56B and the p-contact 46. Each inductor structure 54-1, 54-2 comprises a continuous traces of conductive material (e.g., metal) at least partially embedded in the passivation material 36 to form a single coil that extends around a peripheral region 61 of the LED chip 320A. All remaining elements of FIG. 10 are identical to those described in connection with FIG. 7, such that the description of FIG. 7 (which incorporates the description of FIG. 2) is hereby incorporated by reference with respect to FIG. 10. Although the LED chip 320A shown in FIG. 10 includes a p-contact 46 and an n-contact 48 that are exposed along the rear surface 22 of the LED chip 20 and that permit the LED chip 320A to be conductively coupled to an external current source, such contacts 46, 48 (as well as the inductor structures 54-1, 54-1 and distal capacitor plates 56B) need not be exposed in certain embodiments; it is to be appreciated that these elements may be encased in passivation material (e.g., including a rear portion 36′ of passivation material 36 as shown in FIG. 3) and therefore spaced apart from the rear surface 22 of the LED chip 320A.

In operation of the LED chip 320A, a first RF signal generated by an external source (not shown) is received by the first inductor structure 54-1, causing current to be conducted through conductive trace 55-1 to the proximal capacitor plate 56A, thereby causing charge to accumulate between the capacitor plates 56A, 56B. Separately, or additionally, a second RF signal generated by an external source (not shown) is received by the second inductor structure 54-2, causing current to be conducted through conductive trace 55-2 to the proximal capacitor plate 56A, thereby causing charge to accumulate between the capacitor plates 56A, 56B. When sufficient charge has accumulated between the capacitor plates 56A, 56B, current will flow from the proximal capacitor plates 56A through the n-type layer 28, the active layer 30, the p-type layer 26, the current spreading layer 24, the reflector layer 38, the barrier layer 42, the p-contact 46, and the memristor 64 to the distal capacitor plate 56B, causing photons (light) to be emitted by the active layer 30. Such light is reflected by the reflector layer 30 toward the substrate 32 to exit through the light extraction surface 21. If a sufficiently high level of charge is supplied to the memristor element 64, then a resistance value thereof may be altered and maintained in an altered state, thereby altering amount of current that may be supplied to the active layer 30 and altering emissions of the LED chip 320A. If desired, the altered resistance value of the memristor element 64 may be returned to an original state by heating the LED chip 320A. Since the LED chip 320 in the illustrated embodiment includes exposed electrical contacts (i.e., n-contact 48 and p-contact 46), the LED chip 320A may also be operated by supplying electrical potential across the electrical contacts 46, 48.

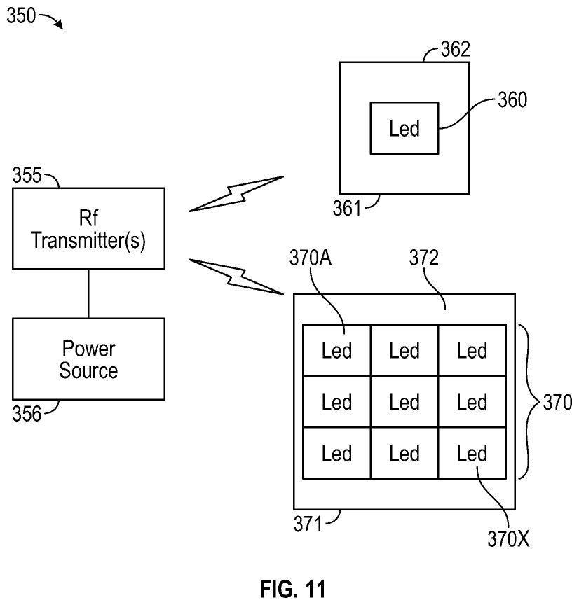

FIG. 11 schematically illustrates a system 350 configured to permit wireless communication between one or more RF transmitters 355 (having an associated power source 356 such as a battery or grid-tied power source) and LED chips 360, 370A-370X, having integrated inductor structures (not shown) configured for harvesting power from signals generated by the one or more RF transmitters 355. The term “RF transmitter” as used herein is to be construed to further include resonant wireless charger apparatuses. The LED chips 360, 370A-370X may be mounted on support elements 362, 372 of various types to form devices or articles 371, 372. In certain embodiments, the support elements 362, 372 may be flexible to accommodate being worn by a user. Examples of flexible support elements 362, 372 include sheets or laminates of polymeric materials, foils, fabrics, composites, and combinations thereof. In certain embodiments, the support elements 362, 372 may be rigid in character. In certain embodiments, the LED chips 360, 370A-370X may be removably attached to support elements 362, 372, such as using hook-and-loop tape (Velcro® or the like) or a similar material, permitting the LED chips 360, 370A-370X to be removed or repositioned as desired.

In certain embodiments, an LED chip or support element may include a microcontroller to pass signals and/or information among components of the system 350.

In certain embodiments, LED chips 360, 370A-370X arranged in or on articles 371, 372 may be provided in singular form or arranged in one-, two-, or three-dimensional arrays arranged to output light of a single color or multiple colors. In certain embodiments, multiple LED chips 370A-370X of different colors may be configured to be illuminated with RF signals of different frequencies (i.e., by selecting different inductive elements tuned to receive specific frequencies) to permit operation of different LED chips 370A-370X to be separately controlled with different RF transmitters 355. In certain embodiments, multiple LED chips 370A-370X may be arrayed and utilized as a sequentially illuminated display. In certain embodiments, the support elements 362, 372 may embody or may be integrated into articles such as clothing, shoes, towels, jewelry, electronic devices, protective cases (e.g., for smartphones, tablet/laptop computers, etc.), upholstery, artwork, credit/debit cards, security access cards, appliances, construction materials, sensors, product packaging, keys, vehicles, indoor or outdoor wireless lighting installations, and other articles. In certain embodiments, output emissions of LED chips 360, 370A-370X may be analyzed by a light sensor (not shown) to sense output intensity (e.g., lumen) and/or wavelength properties of LED chip emissions to assess usage information of the LED chips 360, 370A-370X. For example, if the LED chips 360, 370A-370X incorporate memristors, output emissions of the LED chips 360, 370A-370X may be affected based on prior exposure to RF signals of sufficient intensity due to alteration of memristor resistance. In certain embodiments, light emissions of the LED chips 360, 370A-370X may be used to confirm proximity of the LED chips 355 to a RF transmitter 355 configured to provide a RF signal of known intensity. This may be useful to provide visual feedback to a user of proximity of an article 361, 362 (e.g., a payment device such as a TAP-enabled credit or debit card) to a terminal (e.g., a wireless payment terminal) having a RF transmitter.

In certain embodiments, the LED chips 360, 370A-370X may be added to or otherwise integrated into wearable articles 361, 371. In certain embodiments, one or more LED chips 360, 370A-370X may be removably attached to support elements 362, 372, thereby permitting the LED chips 360, 370A-370X to be mixed or matched and swapped between articles of clothing based on a user's preference, mood, desire for lighting, or the like. In certain embodiments, multiple LED chips 370A-370X may be assembled and/or operated to provide one or more messages in textual characters and/or symbols.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
an active LED structure comprising an n-type layer, a p-type layer, and an active region arranged between the n-type layer and the p-type layer;
a capacitor structure coupled to the active LED structure;
a first inductor structure coupled to the capacitor structure, the first inductor structure being configured to harvest power from a radio frequency signal; and
a ceramic passivation material contacting at least portions of the each of n-type layer, the p-type layer, the capacitor structure, and the first inductor structure.

2. A light-emitting diode (LED) chip, comprising:
an active LED structure comprising an n-type layer, a p-type layer, and an active region arranged between the n-type layer and the p-type layer;
a capacitor structure coupled to the active LED structure; and
a first inductor structure coupled to the capacitor structure, the first inductor structure being configured to harvest power from a radio frequency signal;
wherein the LED chip has a footprint of no greater than 2.5 mm×2.5 mm or a top area when viewed from above of no more than 6.25 mm².

3. The LED chip of claim 2, further comprising a ceramic passivation material contacting at least portions of the each of n-type layer, the p-type layer, the capacitor structure, and the first inductor structure.

4. The LED chip of claim 2, wherein at least a portion of each of the capacitor structure and the first inductor structure is arranged within 500 microns of the active region.

5. The LED chip of claim 1, wherein at least a portion of each of the capacitor structure and the first inductor structure is arranged within 500 microns of the active region.

6. The LED chip of claim 1, wherein:
the capacitor structure comprises a first proximal electrode coupled to the n-type layer, and comprises a first distal electrode that is separated from the first proximal electrode; and
a portion of the ceramic passivation material is arranged between the first proximal electrode and the first distal electrode.

7. The LED chip of claim 1, further comprising a resistor element arranged in contact with the ceramic passivation material, and coupled between the capacitor structure and the active LED structure.

8. The LED chip of claim 1, further comprising a memristor structure arranged in contact with the ceramic passivation material, and coupled between the capacitor structure and the active LED structure.

9. The LED chip of claim 1, further comprising a substrate that comprises a light-transmissive material and that is configured to permit transmission of at least a portion of light emissions of the active LED structure.

10. The LED chip of claim 9, wherein the substrate comprises a patterned surface including at least one of (a) a plurality of recessed features and (b) a plurality of raised features, wherein the active LED structure is adjacent to the patterned surface of the substrate.

11. The LED chip of claim 9, further comprising at least one reflector layer configured to reflect emissions of active region toward the substrate, wherein the active LED structure is arranged between the substrate and the at least one reflector layer.

12. The LED chip of claim 11, further comprising at least one barrier layer contacting the at least one reflector layer and configured to inhibit migration of metal atoms of the at least one reflector layer.

13. The LED chip of claim 1, comprising a central area laterally surrounded by a peripheral area, wherein the active region is arranged in the central area, and the first inductor structure is arranged in the peripheral area.

14. The LED chip of claim 1, further comprising:
a first electrical contact coupled to the n-type layer; and
a second electrical contact coupled to the p-type layer.

15. The LED chip of claim 14, wherein the second electrical contact is electrically coupled between the p-type layer and the capacitor structure.

16. The LED chip of claim 14, wherein each of the first electrical contact and the second electrical contact is exposed along an exterior of the LED chip.

17. The LED chip of claim 14, wherein the capacitor structure and the first inductor structure are encapsulated within the ceramic passivation material and not exposed along an exterior surface of the LED chip.

18. The LED chip of claim 1, further comprising a second inductor structure.

19. The LED chip of claim 1, having a top area when viewed from above of no more than 6.25 mm².

20. A method for fabricating a light emitting diode (LED) chip, the method comprising:
growing an active LED structure on a substrate, the active LED structure comprising an n-type layer, a p-type layer, and an active region arranged between the n-type layer and the p-type layer;
forming a mesa including mesa sidewalls that bound the active region;
depositing a first metal-containing layer, wherein a central portion of the first metal-containing layer is deposited over the mesa to form a mirror structure, and a peripheral portion of the first metal-containing layer is arranged to form a proximal capacitor electrode;
depositing a ceramic passivation material over the first metal-containing layer;
etching portions of the ceramic passivation material; and
depositing a second metal-containing layer to form a first inductor structure and a distal capacitor electrode.

21. The method of claim 20, wherein the ceramic passivation material comprises an oxide, a nitride, or oxynitride material.

22. The method of claim 20, wherein at least a portion of each of the capacitor structure and the first inductor structure is arranged within 500 microns of the active region.

23. The method of claim 20, further comprising forming a resistor element coupled between the capacitor structure and the active LED structure.

24. The method of claim 20, further comprising forming a memristor structure coupled between the capacitor structure and the active LED structure.

25. The method of claim 20, wherein the substrate comprises a patterned surface including at least one of (a) a plurality of recessed features and (b) a plurality of raised features, wherein the active LED structure is adjacent to the patterned surface of the substrate.

26. The method of claim 20, further comprising forming a first electrical contact coupled to the n-type layer, and forming a second electrical contact coupled to the p-type layer, wherein each of the first electrical contact and the second electrical contact is exposed along an exterior of the LED chip.
